(19) United States
(12) Patent Application Publication
(10) Pub. No.: US 2014/0080249 A1
(43) Pub. Date: Mar. 20, 2014

(54) HEAT TREATMENT BY INJECTION OF A HEAT-TRANSFER GAS

(71) Applicants: Grégory Savidand, Orsay (FR); Daniel Lincot, Antony (FR)

(72) Inventors: Grégory Savidand, Orsay (FR); Daniel Lincot, Antony (FR)

(73) Assignees: CENTRE NATIONAL DE LA RECHERCHE SCIENTIFIQUE-CNRS-, Paris Cedex 16 (FR); ELECTRICITE DE FRANCE, Paris (FR)

(21) Appl. No.: 14/115,664

(22) PCT Filed: May 3, 2012
(86) PCT No.: PCT/FR2012/050994

§ 371 Date: Nov. 5, 2013

(30) Foreign Application Priority Data
May 10, 2011 (FR) 11 54015

(51) Int. Cl. H01L 31/18; H01L 21/677; H01L 21/67

(52) U.S. Cl. CPC H01L 31/1864; H01L 21/67109; H01L 21/67248; H01L 21/6776
USPC 438/93; 34/631; 34/553; 34/526

(57) ABSTRACT

A heat treatment of a precursor that reacts with temperature, and that comprises in particular the steps of: preheating or cooling a heat-transfer gas to a controlled temperature, and injecting the preheated or cooled gas over the precursor. Advantageously, besides the temperature of the heat-transfer gas, the following are also controlled: the flow rate of the gas at the injection over the precursor, and also a distance between the precursor and an outlet for injection of the gas over the precursor, in order to finely control the temperature of the precursor receiving the injected gas.

The invention relates to the field of heat treatments for materials, particular thin film materials, and more specifically the heat treatments known as Rapid Thermal Processing. These methods are typically able to achieve increases of at least 700° C. over a period of about a minute.

This technique is particularly advantageous for annealing semiconductors which have thin films deposited on substrates.

The inertia of the furnace in which the heat treatment is applied is a continual problem in this type of technique. It is difficult to control temperature increases (and also cooling, particularly but not exclusively for quenching effects).

In addition, temperature sensors are conventionally and by necessity positioned close to the heating elements and close to the substrate in order to determine the temperature as accurately as possible. An industrial adaptation of this type of method to substrates of large dimensions therefore incurs significant costs.

Rapid thermal processing methods based on several types of technologies are currently known:
infrared annealing: the wavelengths used are short-infrared (0.76 to 2 μm) or mid-infrared (2 to 4 μm); the temperature of the substrate (and of the layer(s) on the substrate) is controlled by the power emitted by the infrared emitters and can undergo very rapid increases, for example reaching 700° C. in less than a minute;
annealing by advancement within a hot chamber: the substrate travels from a cool chamber to a hot chamber, possibly via a buffer chamber at an intermediate temperature; the temperature increases are controlled by the speed of advancement;
induction annealing: the substrate is placed on a magnetic substrate holder and a magnetic field is applied, creating an induced current in the substrate holder which is thus heated by the Joule effect, heating the substrate.

The first type of method has certain disadvantages, however:
it concerns an indirect annealing process which is achieved using light;
plus the thermal behavior of the reaction chambers is dependent on the optical properties of the substrate;
in addition, it is possible to control the temperature increases but not the quenching effects.
   These factors make it difficult to control the temperature.

The second type of method has the disadvantage of using a hot chamber which therefore remains at a fixed temperature. The chamber must have dimensions adapted to the surface area of the substrate, which increases energy consumption and hence the costs of an industrial application.

The distinct advantage of the third type of method is the speed of the temperature increase (several hundred degrees per second). However, in certain applications, the substrate is made of glass and thus heats much more quickly on its lower face (in contact with the substrate holder) that on its upper face, which creates temperature gradients across the thickness of the glass. The resulting heat stresses often cause the glass to break.

In all the methods presented above, it is difficult or even impossible to measure the actual temperature of the sample. The temperature measurement is always indirect (on the substrate holder, on a wall of the furnace, or other placement).

The invention aims to improve the situation.

To this end it proposes a method for the heat treatment of a precursor that reacts with temperature, comprising the steps of:
preheating or cooling a heat-transfer gas to a controlled temperature, and
injecting the preheated or cooled gas over the precursor.

Heat treatment by injection of a hot gas allows setting the temperature of the substrate and of the thin film that it supports. A gas with a high heat-storage capacity is preferably chosen.

For example, argon is a good candidate, already because it is an inert gas (and therefore will not react in an unwanted manner with the thin film), but also because of its heat-storage capacity. The temperature of the gas therefore climbs very quickly and thus provides heat directly to the surface of the substrate.

It is no longer necessary to position a temperature sensor near the substrate. The gas injection can be continuous. Control of the temperature during heating (and cooling) is advantageously achieved using techniques that are very inexpensive to implement. A tool for managing temperature increases and decreases then allows coupling the controls for both heating and cooling the substrate. Injection of gas at the surface of the substrate allows controlling the actual temperature that is applied.

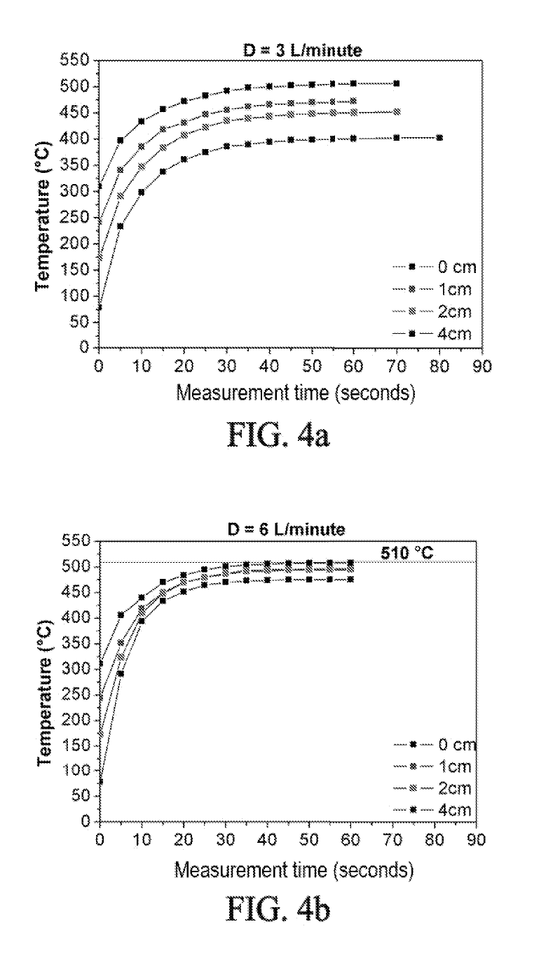

In addition to the temperature of the heat-transfer gas, the flow rate of the gas when it is injected over the precursor is also controlled. As will be seen in reference to FIGS. 4(a) and 4(b), this parameter has an influence on the surface temperature of the precursor receiving the gas injection.

In addition to the temperature of the heat-transfer gas, a distance between the precursor and an outlet for the gas injection over the precursor is also controlled. As will again be seen in reference to FIGS. 4(a) and 4(b) described below, this parameter also has an influence on the surface temperature of the precursor receiving the gas injection.

The heat-transfer gas may contain at least one element from among hydrogen, argon, and nitrogen, these gases being advantageous because of their heat transport capacities.

The preheating of the gas comprises, in a concrete embodiment described below, an increase in the gas temperature on the order of 1000° C.

Under these conditions, injection of the gas produces a temperature increase on the order of tens of degrees per second at the surface of the precursor receiving the gas, for a flow rate of injected gas on the order of several liters per minute (for example between 3 and 6 liters per minute).

The temperature increase of the precursor at its surface can reach at least 400° C. in several tens of seconds, with a distance between the precursor and an outlet for injecting gas over the precursor of less than five centimeters.

For cooling, the method may additionally comprise an injection of cold gas, for example after annealing to produce a quenching effect. Advantageously, the surface of the precursor receiving the cold gas can be cooled at a rate of around 100° C. in a few seconds.

Such an embodiment as described above is advantageous, particularly but not exclusively for a precursor containing atomic species from columns I and III, and possibly VI, of the periodic classification of the elements, in order to obtain on the substrate, after the heat treatment, a thin film of I-III-VI² alloy having photovoltaic properties. It can also be considered for elements from columns I, II, IV, VI (preferably Cu, Zn, Sn, S, or Se) for forming a I₂-II-IV-VI₄ alloy. Elements from column V can also be considered, such as phosphorus, particularly for the creation of II-IV-V alloys (for example ZnSnP).

The invention also concerns a heat treatment installation for carrying out the above method, and comprising:
a gas distribution circuit comprising gas heating means and/or gas cooling means, and
an injector for injecting the gas over the precursor, which ends said circuit.

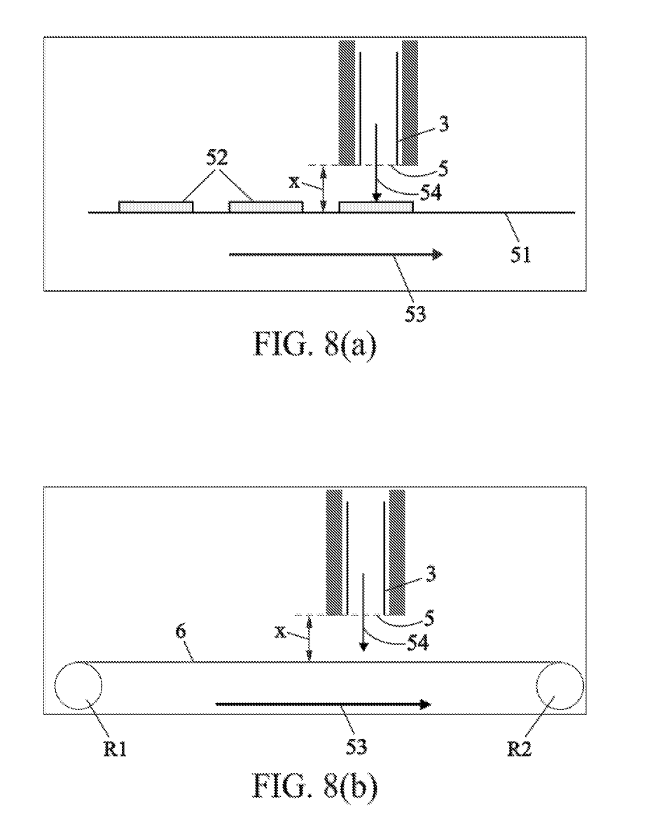

In an example embodiment described in detail below, the injector may simply be in the form of a mouth (labeled with the reference 5 in FIG. 8(a) or FIG. 8(b)) of a pipe (3) for injecting gas over the precursor.

In one possible embodiment, the heating means comprise a thermal resistor able to release heat due to current flowing in the resistor. The heating means may therefore additionally comprise a circuit for controlling the intensity of this current in order to regulate the heating temperature of the resistor, and hence the temperature of the gas to be injected.

The cooling means may comprise a Peltier effect module and/or a cooling circuit, as well as a control circuit for regulating the cooling temperature of the gas.

It is advantageous to provide in the gas distribution circuit at least one gas shutoff valve (for an injection having a binary operation as will be seen in the description below). This valve may also be used for regulating the flow rate of the injected gas.

The installation advantageously comprises means for moving the injector relative to the precursor, at least in height (possibly in a vertical configuration), in order to adjust the distance between the injector and the precursor (and hence the temperature at the surface of the precursor as described below in reference to FIGS. 4(a) and 4(b)).

The installation may also comprise means for moving the precursor, relative to the injector, on a belt traveling in a direction perpendicular to an axis of injection of the gas issuing from the injector. One example of this type of installation for implementing a “batch” type of method will be described below in reference to FIG. 8(a). This type of method is particularly advantageous for precursors deposited on inflexible substrates, for example glass substrates.

In cases where the precursor is a thin film deposited on a flexible substrate, the installation can be designed to operate according to a “roll to roll” type of method. For this purpose, the installation comprises two motorized rollers which the substrate is wound around, and the action of the rollers winds the substrate around one roller and unwinds it from the other roller, causing the precursor to advance, relative to the injector, in a direction perpendicular to an axis of injection of the gas issuing from the injector (FIG. 8(b) in which said rollers are denoted R1,R2).

Of course, other features and advantages of the invention will be apparent from the detailed description of some possible example embodiments, presented below, and the accompanying drawings in which:

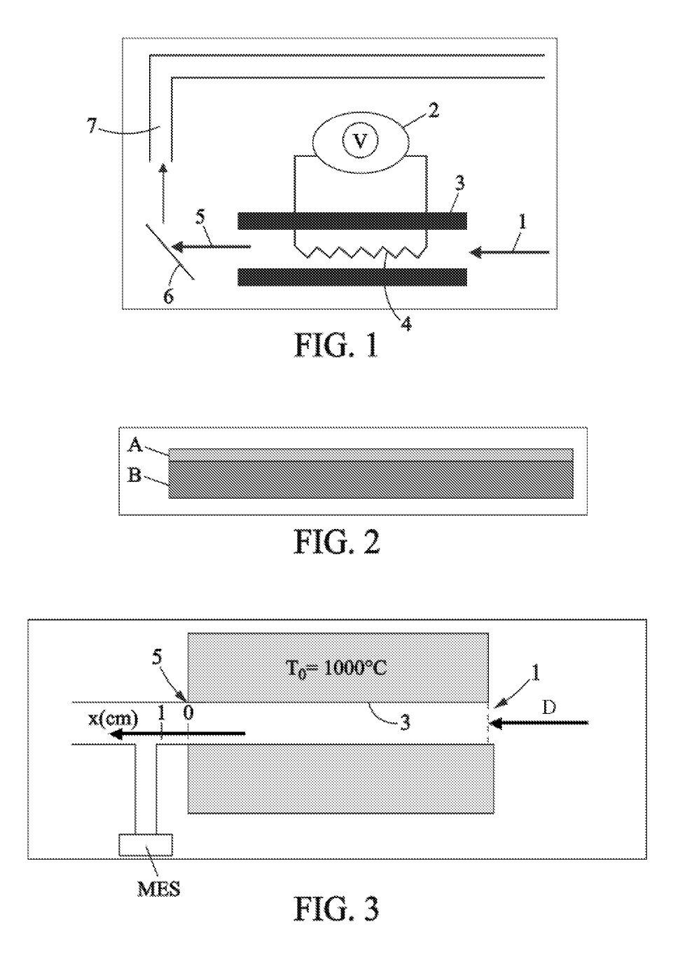

FIG. 1 schematically represents an installation for implementing the invention,

FIG. 2 specifically illustrates an area on a precursor that is annealed by carrying out the method of the invention,

FIG. 3 schematically illustrates a device used for the thermal characterization;

FIGS. 4(a) and 4(b) illustrate the changes over time of the reaction temperature Tr as a function of gas injection parameters such as the flow rate D of the gas in an injection pipe and the distance x between the outlet mouth of this pipe and the precursor, for a flow rate of D=3 liters per minute (a) and D=6 liters per minute (b) respectively;

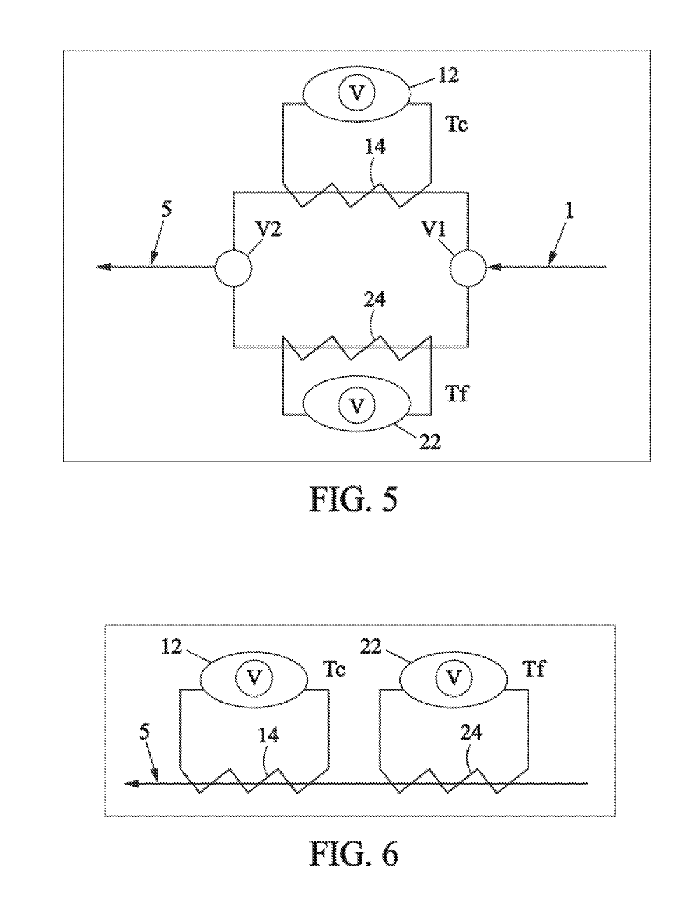

FIG. 5 illustrates a parallel combination of heating elements for controlling the rates at which the gas temperature increases and decreases;

FIG. 6 illustrates a serial combination of heating elements for controlling the rates at which the gas temperature increases and decreases;

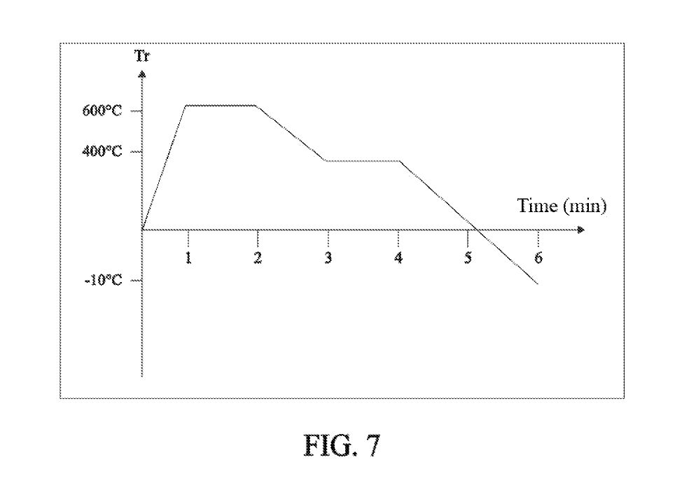

FIG. 7 shows an example of the heat treatment temperature changes that are possible with an installation as presented in FIG. 5 or FIG. 6;

FIGS. 8(a) and 8(b) schematically represent an example where the installation is integrated with an industrial-scale production line, respectively a batch type (a) and a roll-to-roll type (b) implementation.

Below is a non-limiting description of an application of the method of the invention to the production of I-III-VI₂ alloys having a chalcopyrite crystal structure with photovoltaic properties. The intent is to cause a precursor (in thin film format) to react at a controlled pressure in a reactive atmosphere. The “I” (and “III” and “VI”) denotes the elements from column I (respectively III and VI) of the periodic classification of the elements, such as copper (respectively indium and/or gallium and/or aluminum, and selenium and/or sulfur). In a conventional embodiment, the precursor contains group I and III elements, and is obtained in the form of a I-III alloy after a first annealing (“reductive annealing”, defined below). Once the group I and III elements have been combined as the alloy obtained after this first annealing, a reactive annealing is performed in the presence of VI element(s), in order to incorporate them into the I-III alloy and to achieve crystallization of the final chalcopyrite I-III-VI₂ alloy. This reaction is referred to as “selenization” and/or “sulfuration” in this context.

Of course, in another embodiment, the group VI element may also be initially present in the precursor layer and the method of the invention injects a hot gas to anneal the precursor and obtain its crystallization in a I-III-VI₂ stoichiometry.

The description given below uses the following terms:
precursor: a deposit composed of one or more of the following elements: Cu, In, Ga, Al but also possibly Se, S, Zn, Sn, 0, on a substrate;
reductive annealing: annealing the precursor with a gas containing at least one of the following components: alcohol, amines, hydrogen (H₂);
reactive annealing: a crystallization reaction which consists of causing the precursor, which may or may not have undergone a prior reductive annealing, to react with a reactive element;
D: the flow rate of the gas injected over the precursor;
x: distance between the substrate and the mouth of a pipe for injecting gas over the precursor;
T: the temperature of the gas heating components;
Tr: the annealing temperature at the surface of the precursor.

With reference to FIG. 1, an incoming stream of gas 1 undergoes a change in temperature, for example a temperature increase, inside a thermal chamber comprising a pipe 3 containing a heating element 4 to which electrical power 2 is supplied. At the outlet 5 from the pipe 3, the gas has a temperature T(0,D,T0) which is a function of its flow rate D in the pipe 3 and the temperature T₀ of the heating element 4. Reference 6 in FIG. 1 denotes a precursor based on Cu, In, Ga, Zn, Sn, Al, Se, and/or S, undergoing a heat treatment (annealing in the description below) at temperature Tr(x,D,T₀). This annealing temperature Tr here again depends on the flow rate D and on the temperature T₀ of the heating element, but also on the distance x separating the precursor 6 from the mouth 5 of the pipe 3. In addition, there may advantageously be a gas recovery circuit 7. More particularly, the injected gases can be recovered for subsequent reheating and reinjection over the precursor, creating a closed circuit, which is advantageous from a cost aspect.

As illustrated in FIG. 2, the advantages of annealing by propulsion of hot gas include the fact that only the surface A of a precursor on the substrate B is annealed. In effect, it has been observed that the propulsion of the gas directly affects the surface of the precursor and allows localized annealing (area A). The other part (part B) is heated differently (heated to a lesser extent and more importantly at a slower rate).

This property is advantageous, particularly when the substrate is mechanically fragile under conditions involving thermal variations. For example, such is the case with the glass substrates conventionally used in the manufacture of solar panels, on which I-III-VI2 photovoltaic layers are deposited, often with intermediate molybdenum layers.

Thus, a first advantage of such localized annealing on the surface of the precursor is to avoid breakage of the glass substrate.

Measurements of the temperature of a stream of argon exiting the chamber, as a function of:
the distance x to the plane of the pipe 3 outlet 5,
and the flow rate D of the gas
   have been obtained.

In this example embodiment, the gas used is argon at a pressure P of 1 bar at the entry 1 to the installation and is at room temperature (about 20° C.).

The components of a device for measuring the temperature of the gas at the outlet 5 are represented in FIG. 3. A temperature setpoint T₀ (for example T₀=1000° C.) is given to the heating element (for example using a control circuit comprising a variable resistor such as a potentiometer, thus regulating the intensity at the terminals of the heating element 4 such as a resistance heater for example). The flow rate D of the gas can be managed by the degree to which a valve upstream from the inlet 1 (not represented in FIG. 3) is open, and can have a setpoint value D=D₀. However, here the intent is to measure the temperature Tr specifically as a function of the distance x at the outlet 5 from the chamber (given for example in cm by a ruler MES).

The change in the temperature Tr over time, for different measured distances x, is shown in FIG. 4(a) for a gas flow rate D (argon) of 3 liters per minute. The same change over time is represented in FIG. 4(b) but for a flow rate D of 6 liters per minute. Time “0” on the x axis corresponds to the moment the valve that injects gas into the chamber 1 is opened.

One can thus observe that:
the greater the distance from the outlet 5 (increasing the distance x), the greater the decrease in the temperature Tr reached;
the greater the decrease in the flow rate D, the greater the rapid increase in the temperature Tr and the less the dependency of the temperature Tr reached on the distance.

A second advantage of the invention therefore consists of the ability to very closely control the temperature Tr of the gas injected over the precursor, by controlling the flow rate of the gas D and the position x of the substrate relative to the outlet 5.

An installation is represented in FIGS. 5 and 6 which uses a combination of heating/cooling elements of low thermal inertia. FIG. 5 shows a parallel combination of heating and cooling elements. The incoming gas 1 is directed by means of a three-way valve V1 into two circuits (a hot circuit with temperature setpoint Tc and a cold circuit with temperature setpoint Tf). If the gas passes through the hot circuit (containing a resistance heater 14 controlled by an adjustable power supply 12), its temperature is controlled by a control circuit (comprising a potentiometer for example) which sets for example the supply voltage 12. Then, the gas follows its path through a three-way valve V2 and exits the pipe 5 to heat the surface of the precursor. In the case where it is directed by valve V1 into the cold circuit (comprising for example a cooling circuit 24 controlled by a controllable power supply 22), the gas is cooled and its cooling temperature is controlled by a control circuit (comprising a potentiometer for example) which sets for example the supply voltage 22.

When the power supplies 12 and 22 are controllable, it is not necessary to provide two separate pipes (one hot and one cold) and, in reference to FIG. 6, it may be advantageous to make use of a serial combination of heating and cooling elements. The cooling temperature

Tf of the cooling element 24 is controlled by its supply voltage 22, and the same is true for the heating element 14 with its supply voltage 12. In addition, one can make use of the cooling of the cooling element 24 in order to have a cold gas pass through the heating element 14 to accelerate its cooling.

FIG. 7 illustrates an example temperature increase/decrease profile that is advantageous for selenization, applied by combining the variation in the flow rate D with the heat from the elements in FIG. 6, for a precursor position at a fixed distance x.

The temperature of the gas is brought from room temperature (for example 25° C.) to 600° C. in one minute. The temperature of the heating element increases. It is stabilized to maintain a plateau at 600° C. for one minute. Then the cooling element is engaged, in this case cooling the gas to 400° C. within a minute. The supply voltages of the two heating and cooling elements are stabilized and the gas flow rate is kept steady to maintain a plateau for one minute at 400° C. Lastly, the gas is cooled from 400° C. to −10° C. in 2 minutes to produce a quenching effect for example. The heating element is shut off and the cooling element is active during this period.

It is thus understood that the method of the invention can advantageously comprise:
one or more steps of injecting hot gas to produce a temperature increase at the surface of the precursor receiving the gas, on the order of several tens of degrees per second,
one or more steps of holding the precursor at a substantially constant temperature, and
one or more steps of injecting cold gas to produce a temperature decrease at the surface of the precursor receiving the gas, on the order of several tens of degrees per second.

In some cases these steps may be exchanged so that successive periods are defined of heating, holding at temperature, or cooling, as represented in FIG. 7.

In particular, these steps of heating, holding at temperature, or cooling come one after another in a predetermined succession defining a profile for the variation over time of the temperature applied to the surface of the precursor receiving the gas, such as the example profile represented in FIG. 7, for a chosen heat treatment sequence for the precursor.

Below is an example of a possible choice of equipment for controlling the temperature of the injected gas.

For example, resistance heaters (in the form of a strip or wire) composed of an alloy of iron, chrome, nickel and aluminum, capable of rising to 1400° C., may be used for the heating elements 14. These are commercially available (for example those offered by the Swedish company Kanthal®).

For the cooling elements, Peltier effect modules or a circuit of cold gas passing through a pipe coil may be used. Peltier effect modules are thermoelectric cooling systems which function as follows: a difference in potential applied to a module can cool to 18° C. below the room temperature. For a further drop in temperature, there are known vapor compressor systems which allow reaching values below 0° C. There are commercially available gas coolers; some of these products can be found on the site www.directindustry.fr.

By applying the invention, it is possible using hot gas propulsion to achieve ultra-rapid temperature changes, on the order of 500° C. in less than half a minute on the surface of a sample, and to do so without thermal inertia. Integrating the method of the invention into an industrial-scale solar panel production line is particularly advantageous, with rapid annealing requiring very short temperature hold times (from 1 to 5 minutes for void annealing of element VI in the precursor for example).

In reference to FIG. 8(a), samples to be annealed according to a “batch” method advance single file along the line. The samples 52 arrive one behind another on a conveyor belt 51, the belt bringing each precursor under the gas injection pipe 3 (arrow 54) for heat treatment. The belt stops for the time required to treat the precursor. Once the treatment period has ended, the belt brings the next sample by advancing in the direction of advancement 53, and the sequence is repeated. Such a method is particularly suitable when the substrate is inflexible, for example a glass substrate.

We will now describe, in reference to FIG. 8(b), a method in which the substrate 6 is flexible (for example a metal or polymer strip winding between rollers R1, R2 in a “roll-to-roll” process. In this case, the substrate 6 carrying the precursor unwinds from its spool and the treatment is applied directly on its surface (arrow 54).

In a manner similar to the previous embodiment (FIG. 8(a)), the precursor is progressively unwound by the action of the rollers R1, R2. The part to be treated is brought under the injection pipe 3. The unwinding is then stopped. After treatment, another (untreated) part of the precursor is substituted by actuating the rollers R1, R2, and the process is repeated.

The invention can be implemented in a completely automated manner, because a simple solenoid valve at the inlet to the pipe 3 (and/or upstream from the pipe 3) allows a hot (or cold) gas to pass through. An on-off design in the function of such a solenoid valve(s) allows determining the advancement time for the precursor in an exact relation to its processing time.

It is then possible to synchronize the advancement of a precursor and its heat treatment. In particular, one can consider two binary states (injection or non-injection of hot gas) in applying the treatment to the precursor and advancing the precursor. State “1” then corresponds to applying the heat treatment to the precursor, and state “0” corresponds to no heat treatment. Even so, it should be kept in mind that the temperature on the precursor can be closely regulated as a function of:
the flow rate D of the injected gas,
its temperature exiting the pipe 3,
and the distance x between the pipe 3 opening and the precursor to be treated.

One will note that it is possible to vary the height of the outlet mouth of the pipe 3, to regulate the desired temperature of the precursor by moving the mouth vertically.

It is also possible to closely regulate the lateral movement of the mouth (in a direction perpendicular to the advancement of the substrate) in order to conduct a succession of localized heat treatments and therefore anneal the entire substrate surface by movement along the two axes perpendicular to the pipe 3. In this manner one can anneal the entire surface of the substrate, or can apply a localized heat treatment.

It is possible to anneal precursors originating from a prior production step and obtained through various techniques (electrolysis, sputtering, screen printing), possibly in the presence of reactive agents.

An ultra-rapid heat treatment can then be applied to the surface of a substrate, within a very wide range of temperatures (from −50° C. to 1000° C.), while closely controlling the speed of the temperature increases and decreases (via the gas flow rate, the gas temperature, and the position of the substrate).

In another advantage of the invention, the injection of gas over the precursor can be conducted under atmospheric pressure and it is therefore unnecessary to perform the injection within an enclosed chamber under vacuum or at low pressure. The injection can be conducted in the open air.

1. A method for a heat treatment of a precursor that reacts with temperature, comprising the steps of:
providing a heat-transfer gas at a controlled temperature, and
injecting said heat-transfer gas over the precursor.

2. The method according to claim 1, wherein, in addition to the temperature of the heat-transfer gas, the flow rate of said gas when it is injected over the precursor is also controlled.

3. The method according to claim 1, wherein, in addition to the temperature of the heat-transfer gas, a distance between the precursor and an outlet for the gas injection over the precursor is controlled.

4. The method according to claim 1, wherein the heat-transfer gas contains at least one element from among hydrogen, argon, and nitrogen.

5. The method according to claim 1, wherein the preheating of the gas comprises an increase in the gas temperature on the order of 1000° C.

6. The method according to claim 1, wherein the injection of the gas produces a temperature increase on the order of several tens of degrees per second on the surface of the precursor receiving the gas, for a flow rate of injected gas on the order of several liters per minute.

7. The method according to claim 1, wherein the temperature increase of the precursor at its surface reaches at least 400° C. in several tens of seconds, with a distance between the precursor and an outlet for injecting gas over the precursor of less than five centimeters.

8. The method according to claim 1, wherein it comprises an injection of cold gas, producing a cooling of the surface of the precursor receiving the cold gas on the order of 100° C. in a few seconds.

9. The method according to claim 1, wherein it comprises:
one or more steps of injecting hot gas to produce a temperature increase at the surface of the precursor receiving the gas, on the order of several tens of degrees per second,
one or more steps of holding the precursor at a substantially constant temperature, and
one or more steps of injecting cold gas to produce a temperature decrease at the surface of the precursor receiving the gas, on the order of several tens of degrees per second, said heating or cooling steps coming after one another in a predetermined succession defining a profile for the variation over time of the temperature applied to the surface of the precursor receiving the gas, for a chosen heat treatment sequence for the precursor.

10. The method according to claim 1, wherein the precursor comprises atomic species from columns I and III, and possibly VI, of the periodic classification of the elements, in order to obtain on a substrate, after heat treatment, a thin film of I-III-VI₂ alloy having photovoltaic properties.

11. The method according to claim 1, wherein the precursor comprises atomic species from columns I, II, and IV, and possibly VI, of the periodic classification of the elements, in order to obtain on a substrate, after heat treatment, a thin film of I₂-II-IV-VI₄ alloy.

12. The method according to claim 1, wherein the precursor comprises atomic species from columns II and IV, and possibly V, of the periodic classification of the elements, in order to obtain on a substrate, after heat treatment, a thin film of II-IV-V alloy.

13. A heat treatment installation for carrying out the method according to claim 1, comprising:
a gas distribution circuit comprising gas heating means and/or gas cooling means, and
an injector for injecting the gas over the precursor, which ends said circuit.

14. The installation according to claim 13, wherein the heating means comprise a thermal resistor able to release heat due to current flowing in the resistor, and wherein the heating means additionally comprise a potentiometer for controlling the intensity of said current in order to regulate the heating temperature of the resistor.

15. The installation according to claim 13, wherein the cooling means comprise a Peltier effect module and/or a cooling circuit, as well as a potentiometer for regulating the cooling temperature of the gas.

16. The installation according to claim 13, wherein the gas distribution circuit comprises at least one valve for shutting off the gas, and/or for adjusting the flow rate of the injected gas.

17. The installation according to claim 13, wherein it comprises means for moving the injector relative to the precursor, at least in height, in order to adjust the distance between the injector and the precursor.

18. The installation according to claim 13, wherein it comprises means for moving the precursor, relative to the injector, on a belt traveling in a direction perpendicular to an axis of injection of the gas issuing from the injector.

19. The installation according to claim 13, wherein, the precursor being a thin film deposited on a flexible substrate, said installation comprises two motorized rollers which the substrate is wound around, and the action of the rollers winds the substrate around one roller and unwinds it from the other roller, causing the precursor to advance, relative to the injector, in a direction perpendicular to an axis of injection of the gas issuing from the injector.

20. The method of claim 1, wherein said step of providing said heat-transfer gas comprises a preheating of said heat-transfer gas.

21. The method of claim 1, wherein said step of providing said heat-transfer gas comprises a cooling of said heat-transfer gas.
